(19) United States
(12) Patent Application Publication
(10) Pub. No.: US 2025/0274103 A1
(43) Pub. Date: Aug. 28, 2025

(54) Surface Acoustic Wave Filter Module Packaging Structure And Packaging Method Thereof

(71) Applicant: AAC ACOUSTIC TECHNOLOGIES (SHENZHEN) CO., LTD., Shenzhen (CN)

(72) Inventors: Zhiming Zhai, Shenzhen (CN); Chao Wang, Shenzhen (CN); Ying Liu, Shenzhen (CN)

(21) Appl. No.: 18/744,586

(22) Filed: Jun. 14, 2024

Related U.S. Application Data
(63) Continuation of application No. PCT/CN2024/078206, filed on Feb. 23, 2024.

(51) Int. Cl. H03H 9/64; H03H 3/08

(52) U.S. Cl. CPC H03H 9/64; H03H 3/08

(57) ABSTRACT

The present invention provides a surface acoustic wave filter module packaging structure and packaging method thereof. The packaging structure includes a substrate, a surface acoustic wave filter chip, a non-filter chip, a dry film layer, and a plastic sealing layer. The surface acoustic wave filter chip is fixed to the substrate by first convex structures, a first cavity is formed between the surface acoustic wave filter chip and the substrate. The non-filter chip is fixed to the substrate by second convex structures, a second cavity is formed between the non-filter chip and the substrate. The packaging structure and method thereof of the present invention can ensure that a cavity can be formed between the bottom of all chips and the substrate, avoiding the use of injection molding processes based on wafer level packaging filters, reducing costs and damage to chips during reliability testing.

### FIELD OF THE PRESENT INVENTION

The present invention relates to the field of chip packaging technology, and more particularly, to a multi chips module packaging structure and a packaging method thereof.

### DESCRIPTION OF RELATED ART

The working principle of a surface acoustic wave filter is that sound waves are transmitted on a surface of the chip. Therefore, the packaging of the surface acoustic wave filter must ensure that there is sufficient cavity on the surface of the interdigital transducer (the working sensor of the surface acoustic wave filter), otherwise the product will have no signal transmission. At present, the conventional filter RF modules on the market use injection molding packaging solutions based on wafer level packaging. Before packaging the modules, the filter wafers are first packaged at the wafer level to form cavities on the surface of each filter, and then attached to the RF module substrate. Finally, the packaging is completed by injection molding, marking, and cutting.

However, in related art, the packaging solution of filter modules based on wafer level packaging has a high cost and excessive injection pressure, which can lead to reliability risks of the convex structure of chip deformation and cracking. Moreover, when using compression molding (C-Molding), the plastic packaging structure is easy to forming cavities on the surface of the plastic sealing layer, resulting in the instability of the structure.

Therefore, it is desired to provide a new surface acoustic wave filter module packaging structure and a packaging method thereof which can overcome the above problems.

### SUMMARY

In view of the above, the embodiments of the present invention provide a new surface acoustic wave filter module packaging structure, the surface acoustic wave filter module packaging structure can ensure that a cavity can be formed between the bottom of all chips and the substrate, resulting in high reliability.

The present invention provides a surface acoustic wave filter module packaging structure including a substrate, at least one surface acoustic wave filter chip located on the substrate, at least one non-filter chip located on the substrate and spaced apart from the surface acoustic wave filter chip, a dry film layer covering the surface acoustic wave filter chip and the non-filter chip, and a plastic sealing layer covering the dry film layer. The surface acoustic wave filter chip is fixed to the substrate by a plurality of first convex structures on a surface of the surface acoustic wave filter chip, and a first cavity is formed between the surface acoustic wave filter chip and the substrate. The non-filter chip is fixed to the substrate by a plurality of second convex structures on a surface of the non-filter chip, and a second cavity is formed between the non-filter chip and the substrate.

As an improvement, the dry film layer attaches and covers the surface acoustic wave filter chip and the non-filter chip by vacuum airbag lamination.

As an improvement, the dry film layer is a continuous and a whole protective film.

As an improvement, the dry film layer is made of epoxy resin material.

As an improvement, a thickness of the dry film layer is 40-50 microns.

As an improvement, a diameter of each first convex structure is 180-200 microns, and/or the diameter of each second convex structure is 180-200 microns.

As an improvement, a solder mask layer is provided between the substrate and the dry film layer, and the solder mask layer is also provided in a position without the first convex structures in the first cavity.

In view of the above, the embodiments of the present invention also provide a new packaging method of a surface acoustic wave filter module packaging structure, the surface acoustic wave filter module packaging structure made by this method can ensure that a cavity can be formed between the bottom of all chips and the substrate, resulting in high reliability.

The present invention provides a packaging method of a surface acoustic wave filter module packaging structure, including: providing a substrate; providing at least one surface acoustic wave filter chip and at least one non-filter chip, a plurality of first convex structures located on a surface of the surface acoustic wave filter chip, and a plurality of second convex structures located on a surface of the non-filter chip; inverting the surface acoustic wave filter chip and the non-filter chip, and soldering the surface acoustic wave filter chip and the non-filter chip on the surface of the substrate through surface mount technology to form a first cavity between the surface acoustic wave filter chip and the substrate, and a second cavity between the non-filter chip and the substrate; providing a dry film layer covering the surface acoustic wave filter chip and the non-filter chip; providing a plastic sealing layer, the plastic sealing layer covering the dry film layer through injection molding; and cutting to form a plurality of the surface acoustic wave filter module packaging structure, and each surface acoustic wave filter module packaging structure including the surface acoustic wave filter chip and the non-filter chip.

As an improvement, the packaging method further includes: covering a solder mask layer on the substrate when providing the substrate.

As an improvement, a thickness of the dry film layer is 40-50 microns.

### BRIEF DESCRIPTION OF THE DRAWINGS

Many aspects of the exemplary embodiments can be better understood with reference to the following drawing. The components in the drawing are not necessarily drawn to scale, the emphasis instead being placed upon clearly illustrating the principles of the present invention. Moreover, in the drawings, like reference numerals designate corresponding parts throughout the several views.

FIG. 1 is a flowchart of the manufacturing method for a surface acoustic wave filter module packaging structure in accordance with one embodiment of the present invention.

FIGS. 2a to 2e are illustrative views of the manufacturing process for the surface acoustic wave filter module packaging structure of the present invention.

### DETAILED DESCRIPTION OF THE EXEMPLARY EMBODIMENTS

The present invention will hereinafter be described in detail with reference to exemplary embodiments. To make the technical problems to be solved, technical solutions and beneficial effects of the present invention more apparent, the present invention is described in further detail together with the figures and the embodiments. It should be understood the specific embodiments described hereby is only to explain the disclosure, not intended to limit the disclosure.

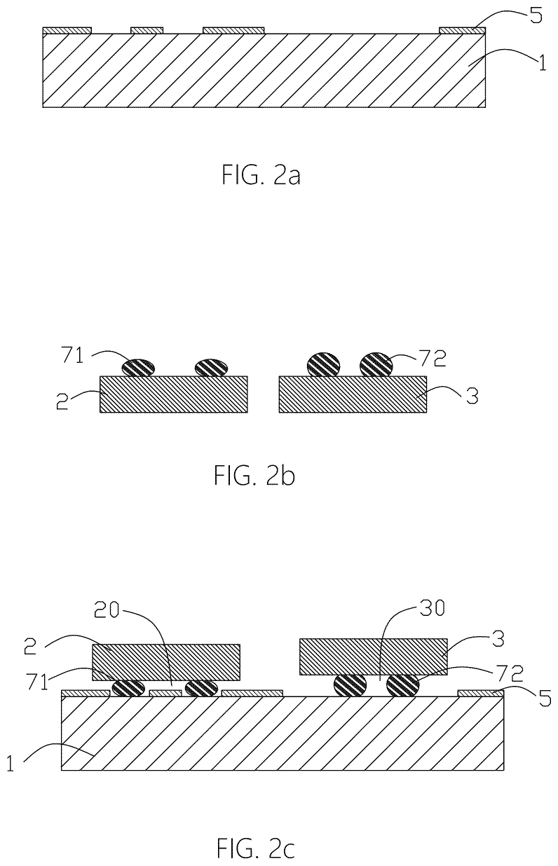

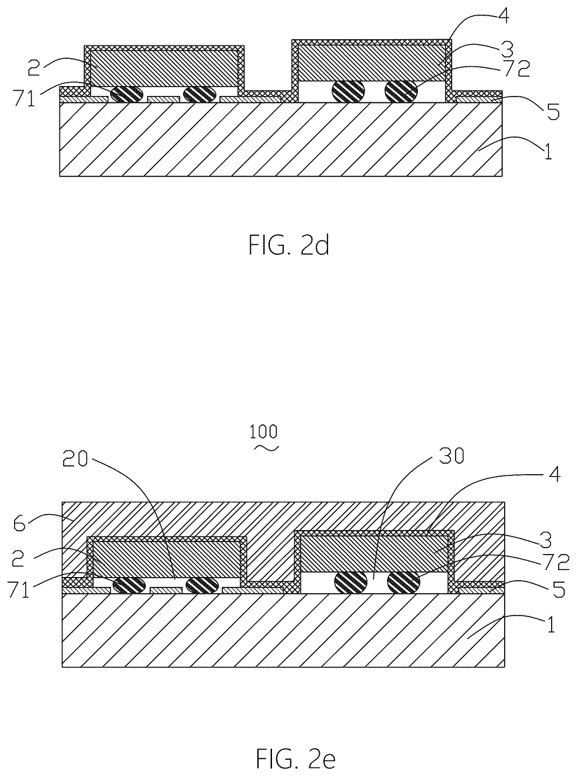

Referring to the FIG. 2e, the present invention provides one embodiment of a surface acoustic wave filter module packaging structure 100. The surface acoustic wave filter module packaging structure 100 includes a substrate 1, at least one surface acoustic wave filter chip 2 located on the substrate 1, at least one non-filter chip 3 located on the substrate 1 and spaced apart from the surface acoustic wave filter chip 2, a dry film layer 4 covering the surface acoustic wave filter chip 2 and the non-filter chip 3, a solder mask layer 5 is provided between the substrate 1 and the dry film layer 4, and a plastic sealing layer 6 covering the dry film layer 4. The surface acoustic wave filter chip 2 is fixed to the substrate 1 by a plurality of first convex structures 71 on a surface of the surface acoustic wave filter chip 2, and a first cavity 20 is formed between the surface acoustic wave filter chip 2 and the substrate 1. The non-filter chip 3 is fixed to the substrate 1 by a plurality of second convex structures 72 on a surface of the non-filter chip 3, and a second cavity 30 is formed between the non-filter chip 3 and the substrate 1.

The dry film layer 4 attaches and covers the surface acoustic wave filter chip 2 and the non-filter chip 3 by vacuum airbag lamination. The dry film layer 4 is a continuous and a whole protective film. Therefore, the dry film layer 4 can prevent other substances entering between the surface acoustic wave filter chip 2 and the substrate 1, ensuring that the first cavity 20 can be formed between the surface acoustic wave filter chip 2 and the substrate 1. Similarly, the dry film layer 4 also can prevent other substances entering between the non-filter chip 3 and the substrate 1, ensuring that the second cavity 30 can be formed between the non-filter chip 3 and the substrate 1. The dry film layer 4 is made of epoxy resin material. A thickness of the dry film layer 4 is 40-50 microns.

The solder mask layer 5 locates on the surface of the substrate 1. The solder mask layer 5 is also provided in a position without the first convex structures 71 in the first cavity 20. The second cavity 30 is not equipped with the solder mask layer 5, so that the adjacent first convex structures 71 and other circuits on the substrate 1 will not be tinned together, thus it will not cause a short circuit in the circuit.

The first convex structures 71 and the second convex structures 72 are both tin balls. A diameter of each first convex structure 71 is 180-200 microns, and/or the diameter of each second convex structure 72 is 180-200 microns.

The plastic sealing layer 6 is covered on the dry film layer 4 through the compression molding (C-molding) to complete the process of plastic sealing. The plastic sealing layer 6 is made of epoxy resin material, and the material composition ratio of the epoxy resin forming the plastic sealing layer 6 is different from that of the epoxy resin forming the dry film layer 4.

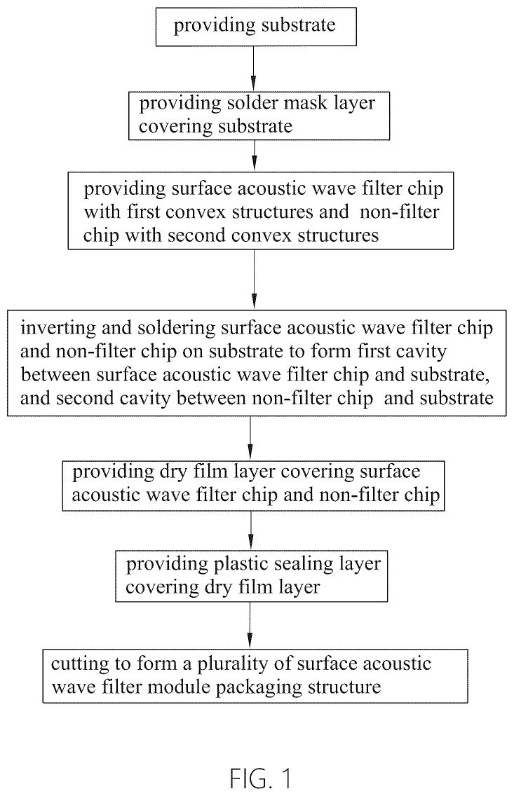

Referring to the FIGS. 1 to 2e, the embodiments of the present invention also provide a new packaging method of a surface acoustic wave filter module packaging structure 100, including:
S1: providing a substrate 1;
S2: providing a solder mask layer 5, the solder mask layer 5 covering on the substrate 1, removing part of the solder mask layer 5 to avoid the chips;
S3: providing at least one surface acoustic wave filter chip 2 and at least one non-filter chip 3, a plurality of first convex structures 71 located on a surface of the surface acoustic wave filter chip 2, and a plurality of second convex structures 72 located on a surface of the non-filter chip 3, the first convex structures 71 and the second convex structures 72 being both tin balls, the diameter of each first convex structure 71 being 180-200 microns, and/or the diameter of each second convex structure 72 being 180-200 microns;
S4: inverting the surface acoustic wave filter chip 2 and the non-filter chip 3, and soldering the surface acoustic wave filter chip 2 and the non-filter chip 3 on the surface of the substrate 1 through surface mount technology to form a first cavity 20 between the surface acoustic wave filter chip 2 and the substrate 1, and a second cavity 30 between the non-filter chip 3 and the substrate 1;
S5: providing a dry film layer 4 covering the surface acoustic wave filter chip 2 and the non-filter chip 3, the dry film layer 4 being made of epoxy resin material, the thickness of the dry film layer 4 being 40-50 microns;
S6: providing a plastic sealing layer 6, the plastic sealing layer 6 covering the dry film layer 4 through injection molding, the plastic sealing layer 6 being made of epoxy resin material;
S7: cutting to form a plurality of the surface acoustic wave filter module packaging structure 100, and each surface acoustic wave filter module packaging structure 100 including the surface acoustic wave filter chip 2 and the non-filter chip 3.

The surface acoustic wave filter module packaging structure 100 made by this method can ensure that the cavity can be formed between the bottom of all chips and the substrate 1, resulting in high reliability.

Comparing with the related art, the present invention provides a surface acoustic wave filter module packaging structure including a substrate, at least one surface acoustic wave filter chip located on the substrate, at least one non-filter chip located on the substrate and spaced apart from the surface acoustic wave filter chip, a dry film layer covering the surface acoustic wave filter chip and the non-filter chip, and a plastic sealing layer covering the dry film layer. The surface acoustic wave filter chip is fixed to the substrate by a plurality of first convex structures on a surface of the surface acoustic wave filter chip, and a first cavity is formed between the surface acoustic wave filter chip and the substrate. The non-filter chip is fixed to the substrate by a plurality of second convex structures on a surface of the non-filter chip, and a second cavity is formed between the non-filter chip and the substrate. The surface acoustic wave filter module packaging structure of the present invention can ensure that the cavity can be formed between the bottom of all chips and the substrate, avoiding the use of injection molding processes based on wafer level packaging filters, reducing costs and damage to chips during reliability testing.

Comparing with the related art, the present invention also provides a packaging method of a surface acoustic wave filter module packaging structure, including: providing a substrate; providing at least one surface acoustic wave filter chip and at least one non-filter chip, a plurality of first convex structures located on a surface of the surface acoustic wave filter chip, and a plurality of second convex structures located on a surface of the non-filter chip; inverting the surface acoustic wave filter chip and the non-filter chip, and soldering the surface acoustic wave filter chip and the non-filter chip on the surface of the substrate through surface mount technology to form a first cavity between the surface acoustic wave filter chip and the substrate, and a second cavity between the non-filter chip and the substrate; providing a dry film layer covering the surface acoustic wave filter chip and the non-filter chip; and providing a plastic sealing layer, the plastic sealing layer covering the dry film layer through injection molding; and cutting to form a plurality of the surface acoustic wave filter module packaging structure, and each surface acoustic wave filter module packaging structure including the surface acoustic wave filter chip and the non-filter chip. The surface acoustic wave filter module packaging structure made by this method of present invention can ensure that the cavity can be formed between the bottom of all chips and the substrate, avoiding the use of injection molding processes based on wafer level packaging filters, reducing costs and damage to chips during reliability testing.

It is to be understood, however, that even though numerous characteristics and advantages of the present exemplary embodiments have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A surface acoustic wave filter module packaging structure, comprising:
a substrate,
at least one surface acoustic wave filter chip located on the substrate, the surface acoustic wave filter chip fixed to the substrate by a plurality of first convex structures on a surface of the surface acoustic wave filter chip, a first cavity formed between the surface acoustic wave filter chip and the substrate;
at least one non-filter chip located on the substrate and spaced apart from the surface acoustic wave filter chip, the non-filter chip fixed to the substrate by a plurality of second convex structures on a surface of the non-filter chip, a second cavity formed between the non-filter chip and the substrate;
a dry film layer covering the surface acoustic wave filter chip and the non-filter chip; and
a plastic sealing layer covering the dry film layer.

2. The surface acoustic wave filter module packaging structure as described in claim 1, wherein the dry film layer attaches and covers the surface acoustic wave filter chip and the non-filter chip by vacuum airbag lamination.

3. The surface acoustic wave filter module packaging structure as described in claim 2, wherein the dry film layer is a continuous and a whole protective film.

4. The surface acoustic wave filter module packaging structure as described in claim 2, wherein the dry film layer is made of epoxy resin material.

5. The surface acoustic wave filter module packaging structure as described in claim 2, wherein a thickness of the dry film layer is 40-50 microns.

6. The surface acoustic wave filter module packaging structure as described in claim 1, wherein a diameter of each first convex structure is 180-200 microns, and/or the diameter of each second convex structure is 180-200 microns.

7. The surface acoustic wave filter module packaging structure as described in claim 1, wherein a solder mask layer is provided between the substrate and the dry film layer, and the solder mask layer is also provided in a position without the first convex structures in the first cavity.

8. A packaging method of a surface acoustic wave filter module packaging structure, comprising:
providing a substrate;
providing at least one surface acoustic wave filter chip and at least one non-filter chip, a plurality of first convex structures located on a surface of the surface acoustic wave filter chip, and a plurality of second convex structures located on a surface of the non-filter chip;
inverting the surface acoustic wave filter chip and the non-filter chip, and soldering the surface acoustic wave filter chip and the non-filter chip on the surface of the substrate through surface mount technology to form a first cavity between the surface acoustic wave filter chip and the substrate, and a second cavity between the non-filter chip and the substrate;
providing a dry film layer covering the surface acoustic wave filter chip and the non-filter chip;
providing a plastic sealing layer, the plastic sealing layer covering the dry film layer through injection molding; and
cutting to form a plurality of the surface acoustic wave filter module packaging structure, and each surface acoustic wave filter module packaging structure comprising the surface acoustic wave filter chip and the non-filter chip.

9. The packaging method of the surface acoustic wave filter module packaging structure as described in claim 8, wherein the packaging method further comprises: covering a solder mask layer on the substrate when providing the substrate.

10. The packaging method of the surface acoustic wave filter module packaging structure as described in claim 8, wherein a thickness of the dry film layer is 40-50 microns.
